(19) United States
(12) Patent Application Publication
(10) Pub. No.: US 2015/0034472 A1
(43) Pub. Date: Feb. 5, 2015

(54) TOUCH PANEL

(71) Applicants: Chung-Hsien Li, Taichung City (TW); Kuo-Hsing Chen, New Taipei City (TW); Siang-Lin Huang, Taichung City (TW); Yu-Ting Chen, Taoyuan County (TW); Chien-Liang Chou, New Taipei City (TW)

(72) Inventors: Chung-Hsien Li, Taichung City (TW); Kuo-Hsing Chen, New Taipei City (TW); Siang-Lin Huang, Taichung City (TW); Yu-Ting Chen, Taoyuan County (TW); Chien-Liang Chou, New Taipei City (TW)

(73) Assignee: WINTEK CORPORATION, Taichung City (TW)

(21) Appl. No.: 14/447,622

(22) Filed: Jul. 31, 2014

(30) Foreign Application Priority Data
Jul. 31, 2013 (TW) 102214418

(51) Int. Cl. H03K 17/96; G06F 3/044

(52) U.S. Cl. CPC H03K 17/9622; G06F 3/044; H03K 2217/960705; H03K 2017/9613
USPC 200/5 R

(57) ABSTRACT

A touch panel includes a substrate, first conductive series, second conductive series, and insulation patterns. Each of the first conductive series includes first conductive patterns arranged in a first direction and first narrow portions, and each first narrow portion is connected to two adjacent first conductive patterns. The second conductive series are insulated from the first conductive series. Each of the second conductive series extends in a second direction and includes a plurality of intersections intersected with the first narrow portions. The insulation patterns are located between the first narrow portions and the intersections, so that one of the first narrow portions and a respective one of the intersections intersected with the one of the first narrow portions are separate. An edge of each of the insulation patterns and one of the first conductive patterns of each of the first conductive series partially overlap.

### CROSS-REFERENCE TO RELATED APPLICATION

This application claims the priority benefit of Taiwan application serial no. 102214418, filed on Jul. 31, 2014. The entirety of the above-mentioned patent application is hereby incorporated by reference herein and made a part of this specification.

### FIELD OF THE INVENTION

The invention relates to a touch apparatus; more particularly, the invention relates to a projective capacitive touch panel.

### DESCRIPTION OF RELATED ART

With the blooming development in the electronic technology and the prevalence of wireless communication and the interne, touch panels are often employed as human-machine interfaces between human beings and smart devices to perform control functions. The well-known touch panels include resistive touch panels and capacitive touch panels, in which the capacitive touch panels became an attractive alternative to resistive and other known touch panels for a variety of reasons, including good optical properties, reliability, performance, and cost. Capacitive touch panels detect the location of touch based on a change in capacitance. There are many types of the capacitive touch panels. For instance, one of the projective capacitive touch panels includes a plurality of sensing pads placed on a substrate, in which the sensing pads are connected in two directions to constitute a plurality of conductive series. The conductive series extending in different directions are intersected with and insulated from each other. The touch points are detected by observing variations in capacitances of the sensing pads induced by touch actions.

In order to minimize the capacitance at the overlapping area of the conductive series arranged in two different directions, the conductive series often include a plurality of narrow parts for intersecting with one another. Accordingly, the sensitivity of detecting the touch points is improved and/or the charging and discharging capabilities of integrated circuits is enhanced. In consideration of reducing the thickness of the touch panel, the conductive series extending in different directions may be electrically independent by using small separated insulators disposed at the intersection areas of the conductive series, respectively, rather than using a continuous insulating layer. In general, the small separated insulators are relatively protrusive which form a non-planar surface for subsequent layers, such that the deposition steps of the subsequent layers and the accuracy of patterning the subsequent layers may be affected. For instance, the thickness or line width of the conductive series above the small separated insulators may be reduced unexpectedly. Besides, if the small separated insulators are not well manufactured, e.g., if the peripheries of the small separated insulators are peeled off, the narrow parts of the conductive series covered by the small separated insulators may be damaged by etchant during subsequent manufacturing steps. The damaged narrow parts of the conductive series may result in open circuits or the likelihood of suffering from electrostatic discharge (ESD) damages. Hence, how to prevent the conductive series from being damaged during the manufacturing or using process is one of the issues to be resolved by manufacturers of touch panels.

### SUMMARY OF THE INVENTION

The invention is directed to a touch panel characterized by favorable quality and reliability, so as to prevent open circuit from occurring in conductive series or resolve the issue of insufficient electrostatic discharge (ESD) protection.

In an embodiment of the invention, a touch panel that includes a substrate, a plurality of first conductive series, a plurality of second conductive series, and a plurality of insulation patterns is provided. Each of the first conductive series and each of the second conductive series are insulated. The first conductive series are disposed on the substrate, and each of the first conductive series includes a plurality of first conductive patterns arranged in a first direction and a plurality of first narrow portions. Each of the first narrow portions connects between two adjacent ones of the first conductive patterns of each of the first conductive series. The second conductive series are disposed on the substrate, and each of the second conductive series extends in a second direction and includes a plurality of intersections intersected with the first narrow portions. The insulation patterns are located between the first narrow portions and the intersections so that one of the first narrow portions and a respective one of the intersections intersected with the one of the first narrow portions are separate. An edge of each of the insulation patterns and one of the first conductive patterns of each of the first conductive series partially overlap. Here, a maximum overlapping length of each of the insulation patterns and one of the first conductive patterns in the first direction is at least 15 μm.

According to an embodiment of the invention, an overlapping area of each of the insulation patterns and the one of the first conductive patterns is not more than half an area of the first conductive pattern.

According to an embodiment of the invention, each of the second conductive series includes a plurality of second conductive patterns, and each of the intersections connects between two adjacent ones of the second conductive patterns of each of the second conductive series. The second conductive patterns and the intersections may be arranged in a continuous manner and are made of the same material. A maximum overlapping length of each of the insulation patterns and one of the second conductive patterns in the second direction may be at least 15 μm. An overlapping area of each of the insulation patterns and one of the second conductive patterns may be not more than half an area of the second conductive pattern.

According to an embodiment of the invention, a profile of the insulation pattern is rhombic, circular, elliptic, or other shape with arc edges or arc angle.

According to an embodiment of the invention, the first conductive patterns and the first narrow portions are arranged in a continuous manner and are made of a same material.

According to an embodiment of the invention, each of the first conductive patterns has a first portion and a second portion electrically connected each other, each of the insulation patterns is formed on a respective one of the first narrow portions and two adjacent ones of the first portions of the first conductive pattern connected by the respective first narrow portion, the second portion of the first conductive pattern covers the first portion and the insulation pattern, the first portions of the first conductive patterns and the first narrow portions are made of a same material. A conductivity of the first portion of each of the first conductive patterns may be greater than a conductivity of the second portion of each of the first conductive patterns.

According to an embodiment of the invention, each of the first conductive series further includes a plurality of first conductive portions, each of the first conductive portions is located between two adjacent first narrow portions and connects between two adjacent ones of the first conductive patterns, and a conductivity of each of the first conductive portions is greater than a conductivity of each of the first conductive patterns. Each of the first conductive patterns may be located between one of the first narrow portions and one of the first conductive portions.

According to an embodiment of the invention, the touch panel further includes an insulating protection layer. The insulating protection layer at least covers the first conductive series, and the insulation protection layer is located between the first conductive series and the second conductive series. A thickness of the insulating protection layer may be less than a thickness of the insulation pattern.

According to an embodiment of the invention, each of the second conductive series further includes a plurality of second conductive patterns and a plurality of second conductive portions, and each of the second conductive portions is located between two adjacent intersections. Here, each of the second conductive patterns is located between each of the second conductive portions and each of the intersections. An area of each of the second conductive patterns is greater than an area of each of the second conductive portions and an area of each of the intersections, and a conductivity of each of the second conductive portions is greater than a conductivity of a material of each of the second conductive patterns. The insulation patterns may be not overlapped with the second conductive portions.

According to an embodiment of the invention, the insulation patterns and a region of the second conductive series excluding the intersections partially overlap.

In an embodiment of the invention, a touch panel that includes a substrate, a plurality of first conductive series, a plurality of second conductive series, and a plurality of insulation patterns is provided. Each of the first conductive series and each of the second conductive series are insulated. The first conductive series are disposed on the substrate, and each of the first conductive series includes a plurality of first conductive patterns arranged in a first direction and a plurality of first narrow portions. Each of the first narrow portions connects between two adjacent ones of the first conductive patterns of each of the first conductive series. The second conductive series are disposed on the substrate, and each of the second conductive series extends in a second direction and includes a plurality of intersections intersected with the first narrow portions. The insulation patterns are located between the first narrow portions and the intersections so that one of the first narrow portions and a respective one of the intersections intersected with the one of the first narrow portions are separate. Here, the insulation patterns and the first conductive patterns partially overlap.

According to an embodiment of the invention, the insulation patterns and a region of the second conductive series excluding the intersections partially overlap.

According to an embodiment of the invention, the region of the second conductive series excluding the intersections partially covers the insulation patterns.

In view of the above, the insulation patterns of the touch panel are extended from the first narrow portions to be overlapped with the first conductive patterns, thereby the first narrow portions can be protected from being affected by etchant or electrostatic discharge in subsequent manufacturing steps. Accordingly, electrically connection between the first narrow portions and the first conductive patterns of each of the first conductive series can be ensured. Moreover, the insulation patterns are extended from the intersections to be overlapped with the region of the second conductive series excluding the intersections, and therefore the likelihood of open circuit in the intersections may be reduced. The non-intersections (e.g., the second conductive patterns) in the second conductive series partially covers the insulation patterns, such that the insulation patterns are not peeled off from the surface to which the insulation patterns are attached. As discussed above, the insulation patterns are relatively protrusive. Hence, if the conductive series are extended from the surface of the substrate to the top of the insulation patterns, the conductive series can still be arranged in a continuous manner and are not easily separated from each other or one another even though the linewidth of the conductive series may be reduced. As a result, it is rather unlikely for the conductive series of the touch panel to be poorly manufactured, and sufficient ESD protection can be ensured. That is, the touch panel described herein is characterized by favorable quality and reliability.

Several exemplary embodiments accompanied with figures are described in detail below to further describe the invention in details.

### BRIEF DESCRIPTION OF THE DRAWINGS

FIG. 1 is a schematic partial top view illustrating a touch panel according to a first embodiment of the invention.

FIG. 2 is a schematic cross-sectional view illustrating the touch panel depicted in FIG. 1 along a section line A-A′.

FIG. 3 is a schematic cross-sectional view illustrating the touch panel depicted in FIG. 1 along a section line B-B′.

FIG. 4 is a schematic partial top view illustrating a touch panel according to a second embodiment of the invention.

FIG. 5 is a schematic partial top view illustrating a touch panel according to a third embodiment of the invention.

FIG. 6 is a schematic partial top view illustrating a touch panel according to a fourth embodiment of the invention.

FIG. 7 is a schematic cross-sectional view illustrating the touch panel depicted in FIG. 6 along a section line C-C′.

FIG. 8 is a schematic cross-sectional view illustrating the touch panel depicted in FIG. 6 along a section line D-D′.

FIG. 9 is a schematic cross-sectional view illustrating a different type of the touch panel depicted in FIG. 6.

FIG. 10 is a schematic top view of a touch panel according to a fifth embodiment of the invention.

FIG. 11A to FIG. 11C illustrate a method of fabricating a touch panel 100A.

FIG. 11D is a schematic cross-sectional view illustrating the touch panel depicted in FIG. 11C along a section line X-X.

FIG. 12A to FIG. 12C illustrate a method of fabricating a touch panel 100B.

FIG. 13A is a schematic top view illustrating a touch panel according to an embodiment of the invention.

FIG. 13B and FIG. 13C are schematic cross-sectional views illustrating the touch panel depicted in FIG. 13A along a section line Y-Y and a section line Z-Z, respectively.

FIG. 14A to FIG. 14C illustrate a method of fabricating a touch panel of the present invention.

FIG. 15 schematically illustrates a portion of the first conductive series and the second conductive series in further other embodiment.

### DETAILED DESCRIPTION OF DISCLOSED EMBODIMENTS

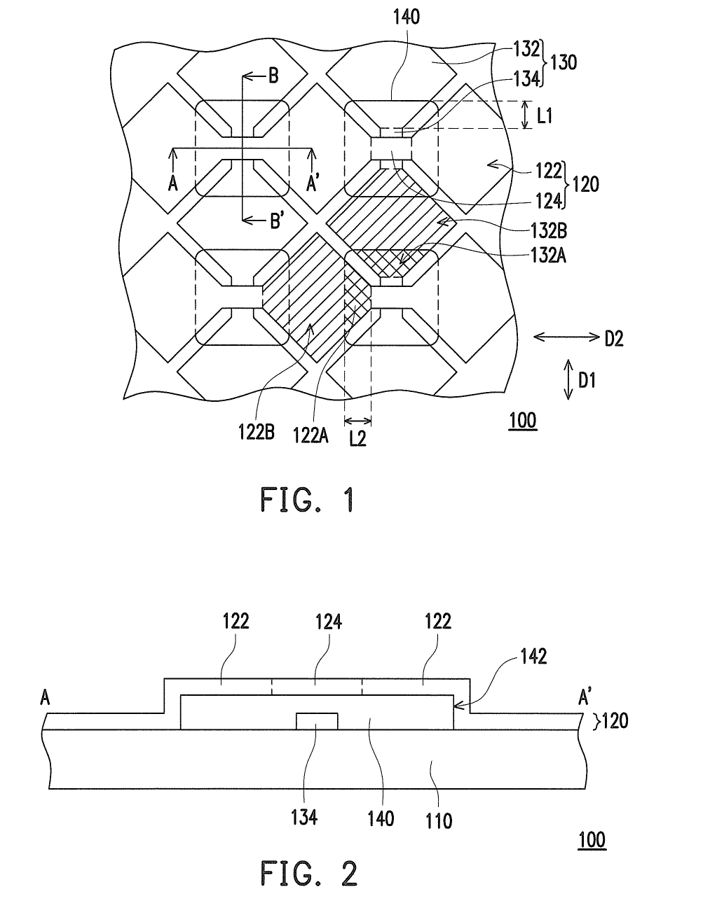

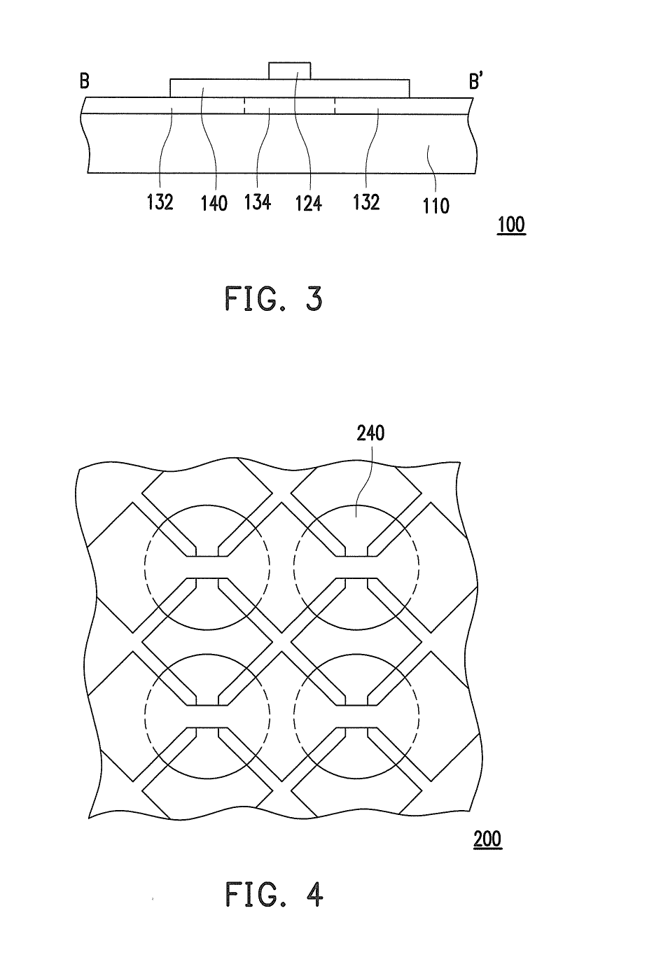

FIG. 1 is a schematic partial top view illustrating a touch panel according to a first embodiment of the invention. FIG. 2 is a schematic cross-sectional view illustrating the touch panel depicted in FIG. 1 along a section line A-A′. FIG. 3 is a schematic cross-sectional view illustrating the touch panel depicted in FIG. 1 along a section line B-B′. With reference to FIG. 1 to FIG. 3, a touch panel 100 includes a substrate 110, a plurality of first conductive series 130, a plurality of second conductive series 120, and a plurality of insulation patterns 140. The first conductive series 130, the second conductive series 120, and the insulation patterns 140 are located on the same side of the substrate 110. The first conductive series 130 and the second conductive series 120 are intersected with each other and electrically independent by disposing the insulation patterns 140 at the intersection areas thereof. Thereby, the touch sensing functions can be performed due to the capacitive effects generated by the first conductive series 130 and the second conductive series 120. Through the first conductive series 130 and the second conductive series 120, when a conductive object, such as finger, approaches to or contacts with an operating surface of the touch panel 100, a change in capacitance effect is generated, and the position of the object or the motion of the object can be detected by a self capacitance measurement method or a mutual capacitance measurement method. The operating surface of the touch panel 100 can be a surface of the substrate 110 where is opposite to the surface where the touch-sensing element 120 disposed on, but the invention is not limited thereto.

Specifically, each of the first conductive series 130 includes a plurality of first conductive patterns 132 and a plurality of first narrow portions 134. In the present embodiment of the invention, the first conductive patterns 132 are connected together in cascade along a first direction D1 through the first narrow portions 134. That is, each of the first narrow portions 134 electrically connects two adjacent ones of the first conductive patterns 132 together along the first direction D1. The first conductive patterns 132 and the first narrow portions 134 can be arranged in a continuous manner. To facilitate the manufacturing process, the first conductive patterns 132 and the first narrow portions 134 may be made of the same material. Each of the second conductive series 120 extends in a second direction D2, and the second conductive series 120 are intersected with and insulated from the first conductive series 130. According to the locations where the second conductive series 120 and the first conductive series 130 are intersected, intersections 124 can be defined in each of the second conductive series 120, and each of the first narrow portions 134 is intersected with one of the intersections 124. In the present embodiment, each of the second conductive series 120 may include a plurality of second conductive patterns 122, and each intersections 124 connects between two adjacent ones of the second conductive patterns 122. An area of each second conductive pattern 122 is greater than an area of each intersection 124. The second conductive patterns 122 and the intersections 124 can be arranged in a continuous manner; besides, in order to facilitate the manufacturing process, the second conductive patterns 122 and the intersections 124 may be made of the same material. Particularly, the first conductive series 130 and the second conductive series 120 are made of an invisible conductive material, which is selected from a transparent conductive material, such as indium tin oxide (ITO), indium zinc oxide (IZO), gallium zinc oxide (GZO), or carbon nanotube-based thin films, highly conductive material with invisible structure, and the combination thereof, but the invention is not limited thereto. Here, the highly conductive material with invisible structure includes nano metallic wires such as nano silver wires or metal mesh constituted by metal wires each having a linewidth less than 10 μm, but not limited thereto. To apply metallic conductive material into a transparent region of the touch panel 100, the linewidth of the metallic conductive material may be less than 5 μm, and the aperture of the metal mesh may be greater than 80%. In general, the first conductive series 130 and the second conductive series 120 are formed by performing a deposition process using the conductive material to form a conductive layer, and patterning the conductive layer to form desired patterns. In the present embodiment, the first narrow portions 134 can have the relatively small linewidth in comparison with other portions of the first conductive series 130, and the intersections 124 can also have the relative small linewidth in comparison with other portions of the second conductive series 120, but the invention is not limited thereto. For example, the intersections 124 are not limited to have the relative small line width in comparison with other portions of the second conductive series 120, and the relative linewidth of the intersections 124 may be adjusted according to the sensing requirement or the electrical requirement of the touch panel 100.

The substrate 110 may be a rigid transparent substrate or a flexible transparent substrate made of a material including, but not limited to, glass and plastic. The substrate 110 may be made of an transparent insulation material selected from a chemically strengthened glass, a polarizer coated with a hard coat layer, a composite laminate composed of poly (methyl methacrylate) (PMMA) and polycarbonate (PC), an ultraviolet curable resin material (e.g., ORGA resin) or other rigid transparent insulation material having protection features like anti-scratch and high mechanical strength. The polarizer can be selected from a linear polarizer or a circular polarizer. Further, other additional optical layer like anti-glare layer or an antireflection layer can be disposed on a surface of the substrate 110 opposite to the surface where the light-shielding layer 140a is disposed on. The thickness and the hardness of the additional optical layer less than the thickness and hardness of the substrate 110. The thickness the substrate 110 ranges between 0.2 mm and 2 mm. A decoration layer can be partially disposed between the substrate 110 and the first conductive series 130, so as to conceal transmission lines connected to the first conductive series 130 and the second conductive series 120.

The insulation patterns 140 are located between the first narrow portions 134 and the intersections 124, thereby each first narrow portion 134 and each intersection 124 are separate. The insulation patterns 140 can be made of transparent organic insulation material, such as photosensitive resin, or transparent inorganic insulation material including nitride or oxide, such as silicon oxide, titanium oxide, silicon nitride and titanium nitride. In the present embodiment, each intersection area of the first conductive series 130 and the second conductive series 120 includes one first narrow portion 134 and one intersection 124, and the insulation patterns 140 are respectively located between one of the first narrow portions 134 and a respective one of the corresponding intersections 124. However, each intersection area of the first conductive series 130 and the second conductive series 120 can include more first narrow portions 134 or more intersections 124, that is, every two adjacent ones of the first conductive patterns 132 can be connected by more than one first narrow portion 134, or every two adjacent ones of the second conductive patterns 122 can be connected by more than one intersections 124. No matter how many the first narrow portion 134 to connect between every two adjacent ones of the first conductive patterns 132, and how many intersections 124 to connect between every two adjacent ones of the second conductive patterns 122, there can be only one insulation pattern 140 at each intersection area of the first conductive series 130 and the second conductive series 120 to separate the first narrow portions and the intersections, but the present invention is not limited thereto. In the present embodiment, as illustrated in FIG. 2 and FIG. 3, each intersection 124 is located on one side of the corresponding insulation pattern 140 away from the substrate 110. Each of the first narrow portions 134 is located between the corresponding insulation pattern 140 and the substrate 110. Hence, the fabricating method of the touch panel 100 includes foi ling the first conductive series 130 on a side of the substrate 110, forming the insulation patterns 140 on the first narrow portions 134, and then forming the second conductive series 120 on the same side of the substrate 110. Here, the second conductive series 120 cross over the insulation patterns 140 and are intersected with the first conductive series 130. The first conductive series 130 are formed prior to the second conductive series 120; hence, to prevent the first conductive series 130 from being affected in subsequent manufacturing steps, during the etch patterning process of the conductive material of the second conductive series 120, the properties of the conductive material of the first conductive series 130 may be different from the properties of the conductive material of the second conductive series 120. Thereby, the etchant applied for patterning the second conductive series 120 poses no impact on the first conductive series 130. For instance, the conductive material of the second conductive series 120 may be ITO that is deposited at a low temperature or has the amorphous characteristics without undergoing annealing thermal treatment; the conductive material of the first conductive series 130 may be ITO that is deposited at a high temperature or has the crystalline characteristics undergoing annealing thermal treatment. Thereby, an oxalic acid solution may be employed during the etch patterning process of the conductive material of the second conductive series 120, so as to prevent the first conductive series 130 made of the crystalline ITO from being affected. In addition, to reduce the impedance of the second conductive series 120, annealing thermal treatment may be performed on the second conductive series 120 after the etch patterning process of the conductive material of the second conductive series 120. While the temperature reaches 150° C. or more, ITO starts to be partially crystallized; however, the invention is not limited thereto because the crystallinity of ITO may be changed if the manufacturing steps, the types of targets, and the operational time frames alter.

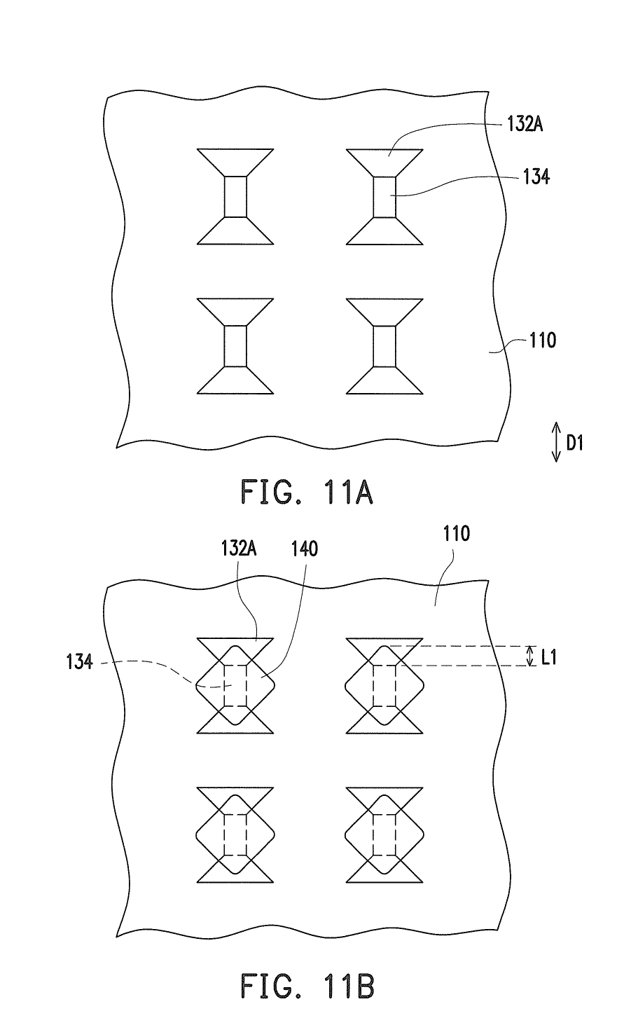

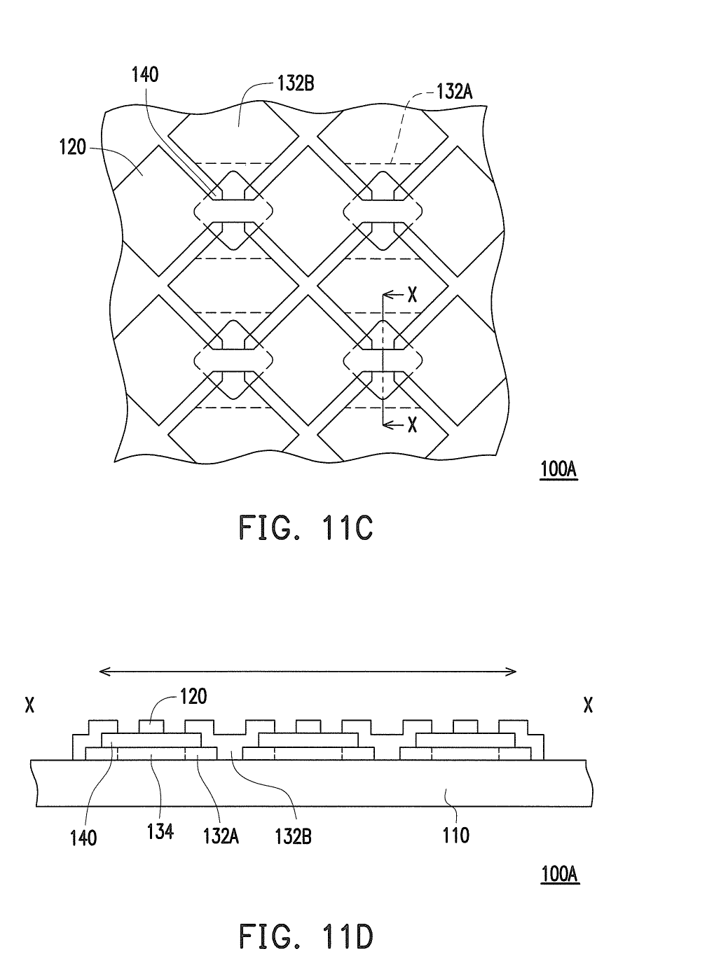

However, the method of fabricating the touch panel 100A provided herein is not limited to that disclosed in the present embodiment. For instance, the method of fabricating the touch panel 100A is shown in FIG. 11A to FIG. 11C. In a first step as shown in FIG. 11A, first portions 132A of the first conductive patterns 132 and the first narrow portions 134 are formed simultaneously on a side of the substrate 110. In a second step as shown in FIG. 11B, the insulation patterns 140 are formed on the first portions 132A and the first narrow portions 134. Here, the first portions 132A of the first conductive patterns 132 are not completely covered by the insulation patterns 140. In a third step as shown in FIG. 11C, second portions 132B of the first conductive patterns 132 and the second conductive series 120 are formed simultaneously on the same side of the substrate 110, in which one of the second portions 132B covers the insulation patterns 140 and a respective one of the first portions 132A of the first conductive patterns 132, and the second conductive series 120 cross over the insulation patterns 140 and intersect with the first conductive series 130. Therefore, each first conductive pattern 132 has the first portion 132A and the second portion 132B, which are formed separately. FIG. 11D is a schematic cross-sectional view illustrating the touch panel depicted in FIG. 11C along a section line X-X. As shown in FIG. 11D, the second portions 132B of the first conductive patterns 132 are electrically connected to the first portions 132A of the first conductive patterns 132 by contacting the first portions 132A. The orthogonal projection of the second portions 132B of the first conductive patterns 132 may be at least partially overlapped with the orthogonal projection of the first portions 132A of the first conductive patterns 132. As illustrated in FIG. 11B, the maximum overlapping length L1 of each of the insulation patterns 140 and the first portion 132A of one of the first conductive patterns 132 in the first direction D1 is at least 15 μm. In the present embodiment, the first narrow portions 134 and the first portions 132A of the first conductive patterns 132 are made of the same conductive material, while the second portions 132B and the first portions 132A of the first conductive patterns 132 are made of different conductive materials or the same conductive material having different properties, but the present invention is not limited thereto. For instance, the first narrow portions 134 and the first portions 132A of the first conductive patterns 132 may be made of metal or a transparent conductive material that undergoes a high-temperature crystallization process, so as to reduce the impedance of the first narrow portions 134 and the first portions 132A of the first conductive patterns 132. Moreover, when the orthogonal projection of the second portions 132B of the first conductive patterns 132 are overlapped with the orthogonal projection of the first portions 132A of the first conductive patterns 132, the second portions 132B and the first portions 132A of the first conductive patterns 132 can be made of the same conductive material. In addition, the coverage of the first portions 132A of the first conductive patterns 132 can be same as the coverage of the second portions 132B of the first conductive patterns 132, so as to reduce the impedance of the first conductive series 130.

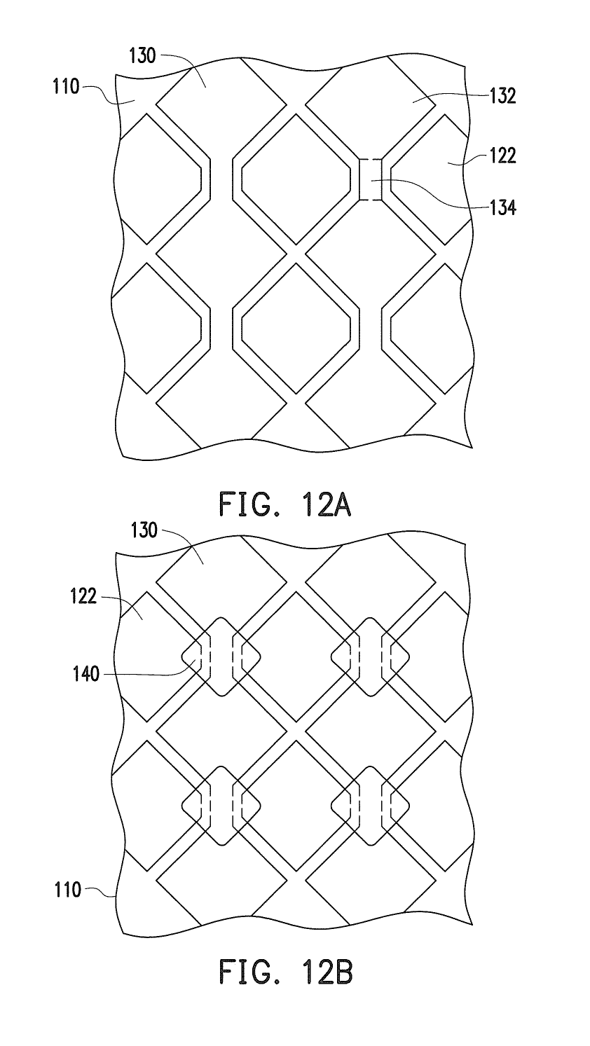

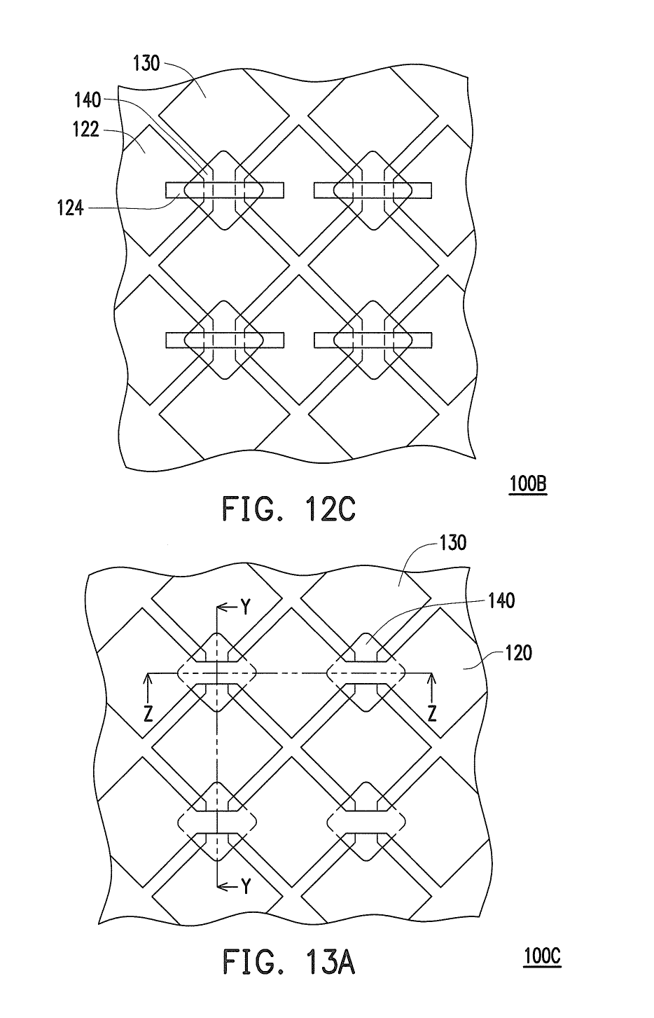

In another embodiment, the fabricating method of the touch panel 100B is shown in FIG. 12A to FIG. 12C. As shown in FIG. 12A, the first conductive series 130 and separated second conductive patterns 122 are simultaneously formed on a side of the substrate 110. As shown in FIG. 12B, the insulation patterns 140 are formed on the first narrow portions 134 and a portion of the first conductive patterns 132. Here, the insulation patterns 140 may partially cover the second conductive patterns 122. As shown in FIG. 12C, the intersections 124 that each connects between two adjacent ones of the second conductive patterns 122 of each of the second conductive series 120 and extends across the insulation patterns 140 are formed on the same side of the substrate 110. The intersections 124 contact the second conductive patterns 122. A conductive material of the intersections 124 is different from that of the first conductive series 130 and that of the second conductive patterns 122. For instance, the first conductive series 130 and the second conductive patterns 122 may be made of ITO having the crystalline characteristics (crystalline ITO), and the conductive material of the intersections 124 may be metal or ITO having the amorphous characteristics. Accordingly, during the etch patterning process of the intersections 124, the etchant that does not affect the first conductive series 130 and the second conductive patterns 122 may be selected, and the electrically connection between the intersections 124 and the second conductive patterns 122 is neither influenced. In addition, the step as shown in FIG. 12C can be replaced with the step as shown in FIG. 11C, such that each first conductive pattern 132 and each second conductive pattern 122 are made of two conductive layers. One conductive layer of each first conductive pattern 132 and one conductive layer of each second conductive pattern 122 are covered by the insulation pattern 140, the other conductive layer of each first conductive pattern 132 and the other conductive layer of each second conductive pattern 122 cover the insulation pattern 140. Accordingly, the impedances of the first conductive series 130 and the second conductive series 120 are reduced, and the yield of the touch panel is increased.

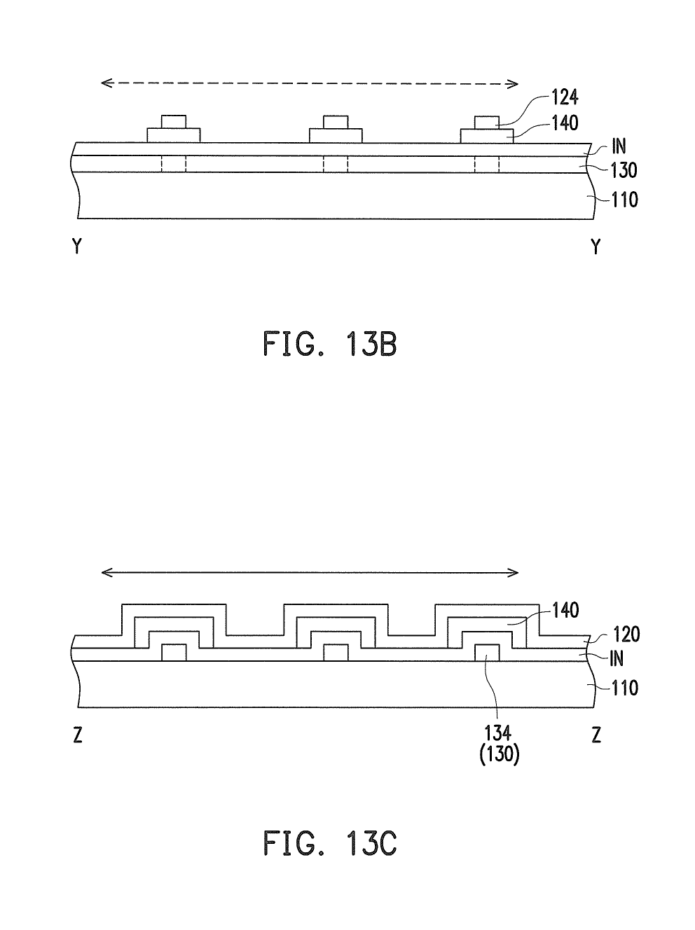

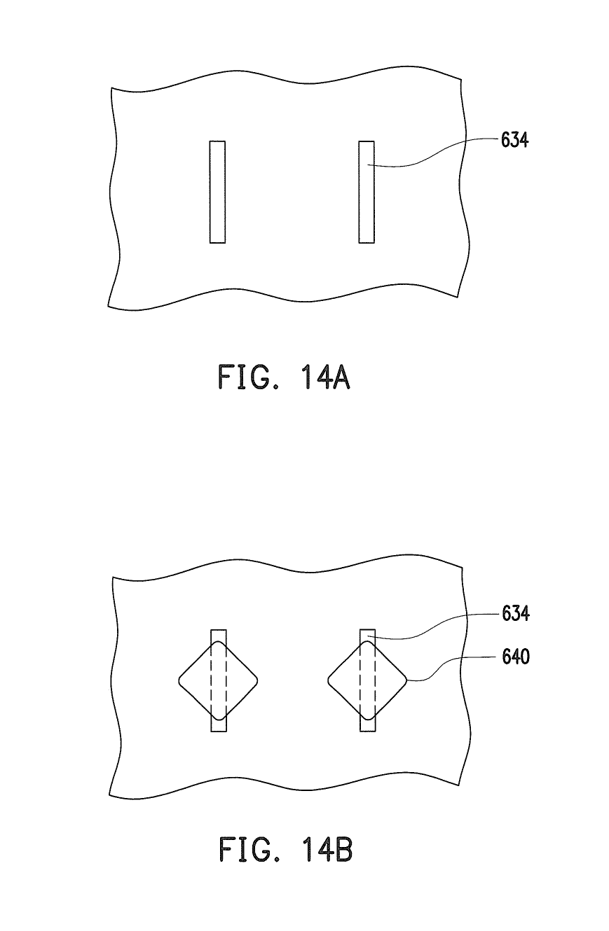

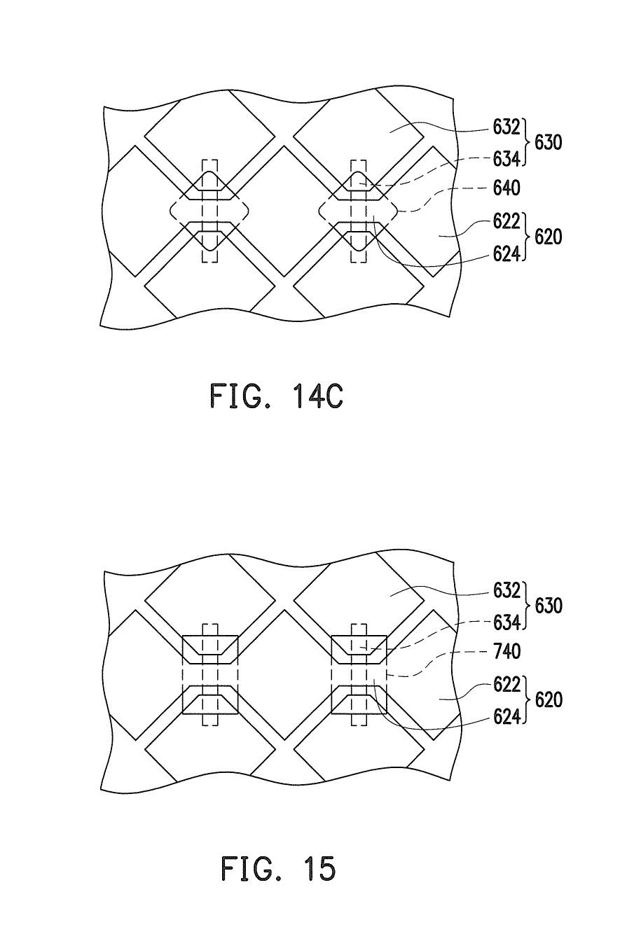

FIG. 13A is a schematic top view illustrating a touch panel according to an embodiment of the invention. FIG. 13B and FIG. 13C are schematic cross-sectional views illustrating the touch panel depicted in FIG. 13A along a section line Y-Y and a section line Z-Z, respectively. With reference to FIG. 13A to FIG. 13C, the touch panel 100C described in the present embodiment is similar to the touch panel 100 described in the first embodiment, and therefore the same components are labeled by the same reference numbers. The first conductive series 130 are formed prior to the second conductive series 120; hence, to prevent the first conductive series 130 from being affected in subsequent manufacturing steps, the touch panel 100C may further include an insulating protection layer IN at least covering the first conductive series 130. The shape of the insulating protection layer IN may be similar to that of the first conductive series 130, and the dimension of the insulating protection layer IN may be equal to or greater than that of the first conductive series 130. Alternatively, the insulating protection layer IN may be a continuous overlay almost covering the substrate 110 and located between the first conductive series 130 and the second conductive series 120, as shown in FIG. 13B and FIG. 13C. Besides, in an alternative embodiment, a touch panel can be made by the fabricating method shown in FIG. 14A to FIG. 14C, the insulating protection layer IN can be optionally made before the step shown in FIG. 14B, and may have plural micro-pores in consideration of the requirements for conductivity and connection. A material of the insulating protection layer IN may be selected from aluminum oxide, niobium oxide, titanium oxide, silicon nitride, silicon oxynitride, silicon oxide, and a combination thereof. Here, the material of the insulating protection layer IN may have the single-layer structure or the multi-layer structure having at least two layers with different refractive indices. Matching the refractive indices of the insulating protection layer IN, the first conductive series 130, and the second conductive series 120 may lead to constructive or destructive interference, so as to reduce the visibility of the first and second conductive series 130 and 120. In addition, a thickness of the insulating protection layer IN can be less than a thickness of the insulation pattern 140, so as to avoid the negative impact of light transmission as well as provide necessary dielectric isolation between the first conductive series 130 and second conductive series 120.

With reference to FIG. 2 and FIG. 3, each of the insulation patterns 140 covers one of the first narrow portions 134 of the first conductive series 130 and a portion of each of the adjacent first conductive patterns 132 connected by the one of the first narrow portions 134. As such, the first narrow portions 134 that are smaller than the first conductive patterns 132 are protected from being negatively affected in the subsequent manufacturing steps. Specifically, in the subsequent manufacturing steps, the first narrow portions 134 may be not damaged by the etchant and may thus not encounter the issue of open circuit, or the resultant linewidth of the first narrow portion 134 is not thinner than the predetermined line width.

In FIG. 2, the insulation patterns 140 are relatively protrusive from the side of the substrate 110, and the second conductive series 120 are formed on the same side of the substrate 110 and cross over the insulation patterns 140, such that the second conductive series 120 are formed on a non-planar surface. However, when the conductive material is deposited on the non-planar surface, the thickness of the deposited material may be uneven. For example, the portion of the second conductive series 120 covering the sidewalls 142 of the insulation patterns 140 may have the relatively thinner thickness. In addition, the accuracy control of the patterning process of the conductive layer is hard to be ensured, such that the portion of the second conductive series 120 covering the sidewalls 142 of the insulation patterns 140 may not be able to have the predetermined line width. For instance, the portion of the second conductive series 120 covering the sidewalls 142 of the insulation patterns 140 may have thinner thickness and narrower linewidth than expected. Therefore, in case of parameters given in the predetermined design being insufficient to compensate the process error, the portion of the second conductive series 120 covering the sidewalls 142 of the insulation patterns 140 is very much likely to encounter the issue of open circuit, and thereby the quality and the reliability of the resultant touch panel 100 may not be satisfactory.

To resolve said issue, each of the insulation patterns 140 described in the present embodiment is not only extended in the first direction to at least partially cover each of the adjacent first conductive patterns 132 connected by the first narrow portion covered by the insulation pattern 140, but also extended in the second direction D2, such that one portion of each second conductive pattern 122 at each of two sides of each intersection 124 covers one portion of each insulation pattern 140. Hence, in the present embodiment, the intersections 124 and parts of the second conductive patterns 122 are formed on the insulation patterns 140. Particularly, the portion of the second conductive series 120 covering the sidewalls 142 of the insulation patterns 140 refers to the second conductive patterns 122 (with the relatively large linewidth) rather than the intersections 124. As a result, the design described herein is capable of reducing the likelihood of open circuit caused by the reduced linewidth or the reduced thickness of the film layers in the existing design.

According to the present embodiment, the maximum overlapping length L1 of each of the insulation patterns 140 and one of the first conductive patterns 132 in the first direction D1 is at least 15 μm. Notwithstanding the subsequent etching process, the sufficient overlapping length L1 ensures the electrically connection between the first narrow portions 134 and the first conductive patterns 132 of the first conductive series 130. Besides, an overlapping area 132A of one of the insulation patterns 140 and one of the first conductive patterns 132 is not more than half an area 132B of the first conductive pattern 132. As shown in FIG. 1, the overlapping area 132A is depicted by backslashes, while the area 132B is depicted by slashes. Accordingly, the peripheries of the insulation patterns 140 are at the coverage of the first conductive patterns 132, so as to prevent the first narrow portions 124 from being exposed by the insulation patterns 140 and reduce the possibility that the first narrow portions 124 encounter the issue of open circuit.

As shown in FIG. 1, the peripheries of the insulation patterns 140 may be at the coverage of the first conductive patterns 132 and may also be at the coverage of the second conductive patterns 122. Thereby, the maximum overlapping length L2 of each of the insulation patterns 140 and one of the second conductive patterns 122 in the second direction D2 may be at least 15 μm as well. Besides, an overlapping area 122A of one of the insulation patterns 140 and one of the second conductive patterns 124 may be not more than half an area 122B of the second conductive pattern 124 in an embodiment of the invention. As shown in FIG. 1, the overlapping area 122A is depicted by backslashes, while the area 122B is depicted by slashes. Note that one portion of each second conductive pattern 122 overlaps one side of each of the insulation patterns 140 away from the substrate 110 in the present embodiment; however, in other embodiments of the invention, one portion of each second conductive pattern 122 may be covered by the insulation pattern 140. In another aspect, a profile of the insulation patterns 140 may be square, and the centers of each insulation pattern 140 correspond to the center of each intersection area of the first conductive series 130 and the second conductive series 120; however, the invention is not limited thereto.

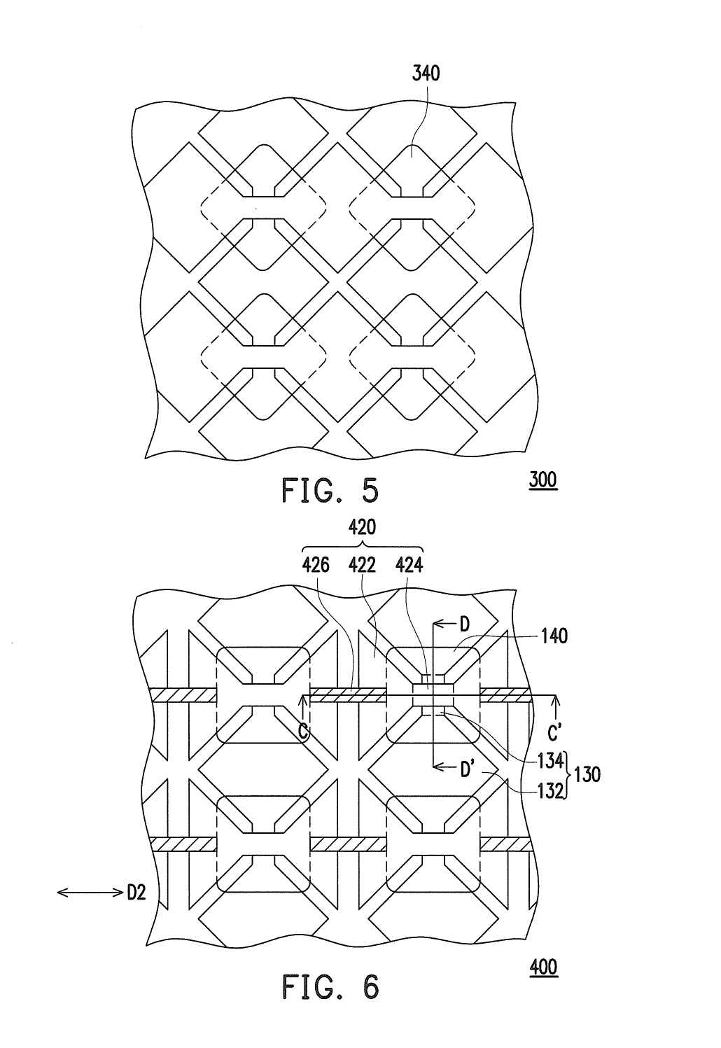

FIG. 4 and FIG. 5 are schematic partial top views illustrating a touch panel according to a second embodiment and a third embodiment of the invention, respectively. With reference to FIG. 4, the touch panel 200 is similar to the touch panel 100, and the difference between the touch panel 200 and the touch panel 100 lies in the profile of the insulation patterns 240. In the touch panel 200, the profile of the insulation patterns 240 is circular or elliptic, for instance. With reference to FIG. 5, the touch panel 300 is similar to the touch panel 100, and the difference between the touch panel 300 and the touch panel 100 lies in the profile of the insulation patterns 340. In order to reduce the chances of the reflected light from the edge of the insulation patterns to be seen, the preferable profile of the insulation pattern is rhombic, circular, elliptic, or other shape with arc edges or arc angle. In the touch panel 300, the profile of the insulation patterns 340 is rhombic, for instance. It should be mentioned that the design of the insulation patterns 140, 240, and 340 is exemplified for illustration and is not intended to limit the scope of the invention. In another embodiment of the invention, the insulation patterns may be elongated patterns extended along the first direction D1 or the second direction D2, such that one insulation pattern can cover more than one intersection area of the first conductive series 130 and the second conductive series 120, that is, the amount of the insulation patterns can be less than the amount of the intersection area. As a whole, as long as the maximum overlapping length L1 in the first direction D1 is at least 15 μm, the design of the insulation patterns falls within the scope of protection of the invention.

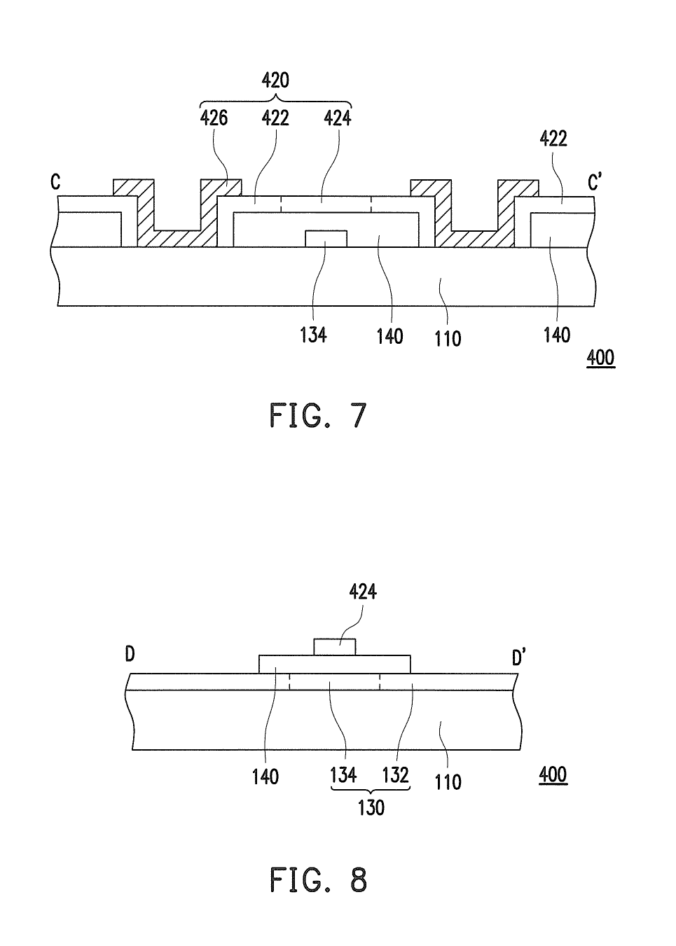

FIG. 6 is a schematic partial top view illustrating a touch panel according to a fourth embodiment of the invention. FIG. 7 is a schematic cross-sectional view illustrating the touch panel depicted in FIG. 6 along a section line C-C′, and FIG. 8 is a schematic cross-sectional view illustrating the touch panel depicted in FIG. 6 along a section line D-D′. With reference to FIG. 6, FIG. 7, and FIG. 8, a touch panel 400 includes a substrate 110, a plurality of first conductive series 130, a plurality of second conductive series 420, and a plurality of insulation patterns 140. The first conductive series 130, the second conductive series 420, and the insulation patterns 140 are located on the same side of the substrate 110. The first conductive series 130 and the second conductive series 420 are intersected with each other and electrically independent by disposing the insulation patterns 140 at the intersection areas thereof. Specifically, the detailed description of the substrate 110, the first conductive series 130, and the insulation patterns 140 can refer to the above embodiments and thus will not be further explained hereinafter. The second conductive series 420, however, are further elaborated below.

According to the present embodiment, each of the second conductive series 420 includes a plurality of second conductive patterns 422, a plurality of intersections 424, and a plurality of second conductive portions 426. The intersections 424 are located within the area occupied by the insulation patterns 140, and each of the intersections 424 serves to connect two adjacent second conductive patterns 422 together along the second direction D2. Besides, each intersection 424 is intersected with one of the first narrow portions 134. Each of the second conductive portions 426 is located between two adjacent intersections 424 and connects between two adjacent second conductive patterns 422 together along the second direction D2. Namely, one side of each second conductive pattern 422 is connected to one adjacent second conductive pattern 422 through one of the intersections 424, and the other side of each second conductive pattern 422 is connected to the other adjacent second conductive pattern 422 through one of the second conductive portions 426. Hence, each second conductive pattern 422 is located between one of the intersections 424 and one of the second conductive portions 426. Note that the second conductive portions 426 are not intersected with the first narrow portions 134.

In the present embodiment, a material of the second conductive portions 426 may be different from a material of the second conductive patterns 422. Specifically, the conductivity of the second conductive portions 426 may be greater than the conductivity of the second conductive patterns 422. For instance, the second conductive patterns 422 and the intersections 424 may be made of a transparent conductive material, and the second conductive portions 426 may be made of metal, metal alloy, a stacked structure containing multiple metal layers characterized by favorable conductivity, or a transparent conductive material layer with low impedance. As such, the arrangement of the second conductive portions 426 having the favorable conductivity is conducive to the improvement of the transmission properties of the second conductive series 420 in the second direction D2.

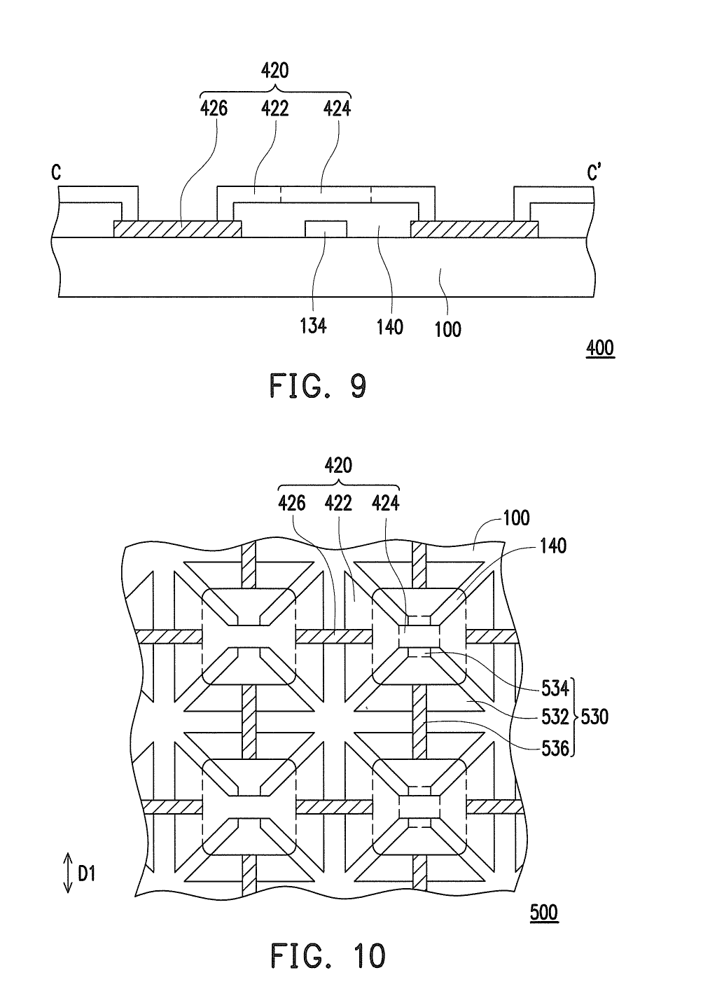

As shown in FIG. 7, the second conductive portions 426 may be formed on the substrate 110 after the second conductive patterns 422 are formed. Hence, the second conductive portions 426 partially cover the second conductive patterns 422, such that one portion of the second conductive patterns 422 is located between the second conductive portions 426 and the substrate 110. However, the invention should not be construed as limited to the embodiments set forth herein. FIG. 9 is a schematic cross-sectional view illustrating a different type of the touch panel depicted in FIG. 6. The steps in the manufacturing process of the touch panel may be performed in a different order, as shown by the cross-section of the touch panel 400 taken along the section line C-C′ in FIG. 9. With reference to FIG. 9, the second conductive portions 426 of the second conductive series 420 may be located between one portion of the second conductive patterns 422 and the substrate 110. Besides, the insulation patterns 140 may partially cover the second conductive portions 426.

FIG. 10 is a schematic top view of a touch panel according to a fifth embodiment of the invention. With reference to FIG. 10, a touch panel 500 includes a substrate 110, a plurality of first conductive series 530, a plurality of second conductive series 420, and a plurality of insulation patterns 140. The first conductive series 530, the second conductive series 420, and the insulation patterns 140 are located on the same side of the substrate 110. The first conductive series 530 and the second conductive series 420 are intersected with each other and electrically independent by disposing the insulation patterns 140 at the intersection areas thereof. Specifically, the detailed description of the substrate 110, the second conductive series 420, and the insulation patterns 140 are described in the above embodiments and thus will not be further explained hereinafter. The first conductive series 530, however, are further elaborated below.

According to the present embodiment, each of the first conductive series 530 includes a plurality of first conductive patterns 532, a plurality of first narrow portions 534, and a plurality of first conductive portions 536. The first narrow portions 534 are located within the area occupied by the insulation patterns 140, and each of the first narrow portions 534 serves to connect two adjacent first conductive patterns 532 together along the first direction D1. Besides, each first narrow portion 534 is intersected with one of the intersections 424. Each of the first conductive portions 536 is located between two adjacent first narrow portions 534 and connects between two adjacent first conductive patterns 532. Namely, one side of one of the first conductive pattern 532 is connected to one adjacent first conductive pattern 532 through one of the first narrow portions 534, and the other side of the one of the first conductive pattern 532 is connected to the other adjacent first conductive pattern 532 through one of the first conductive portions 536. Hence, each first conductive pattern 532 is located between one of the first narrow portions 534 and one of the first conductive portions 536. Note that the first conductive portions 536 are not intersected with the intersections 424.

In the present embodiment, a material of the first conductive portions 536 may be different from a material of the first conductive patterns 532. Specifically, the conductivity of the first conductive portions 536 may be greater than the conductivity of the first conductive patterns 532. For instance, the first conductive patterns 532 and the first narrow portions 534 may be made of a transparent conductive material, and the first conductive portions 536 may be made of metal, metal alloy, or a stacked structure containing multiple metal layers characterized by favorable conductivity. As such, the arrangement of the first conductive portions 536 having the favorable conductivity is conducive to the improvement of the transmission properties of the first conductive series 530 in the first direction D1.

In another embodiment, the fabricating method of the touch panel is shown in FIG. 14A to FIG. 14C. The first conductive series 630, the second conductive series 620, and the insulation patterns 640 are generally similar to the first conductive series 130, the second conductive series 120, and the insulation patterns 140, respectively, thus the same or the similar components in the two embodiments are to be represented with the similar element symbols. The same characteristics are not described here. In a first step as shown in FIG. 14A, the first narrow portions 634 are formed on a side of the substrate 110. In a second step as shown in FIG. 14B, the insulation patterns 640 are formed on the first narrow portions 634. Here, the first narrow portions 634 are not completely covered by the insulation patterns 640. For example, two ends of the first narrow portions 634 are not covered by the insulation patterns 640. In a third step as shown in FIG. 14C, the separated first conductive patterns 632 and the second conductive series 620 are simultaneously formed on a side of the substrate 110. In FIG. 14C, the first conductive series 630 and the second conductive series 620 are intersected with and insulated from each other by disposing the insulation patterns 640 at the intersection areas thereof. Particularly, in the embodiment, each of the first conductive series 630 includes first conductive patterns 632 and first narrow portions 634, wherein the first narrow portions 634 can be formed independently from the first conductive patterns 632 such that each first narrow portion 634 partially overlaps with one of the first conductive patterns 632. Each of the second conductive series 620 includes the second conductive patterns 622 and the intersections 624, wherein a portion of each second conductive pattern 622 overlaps one of the insulation patterns 640. In addition, a portion of each first conductive pattern 632 overlaps one of the insulation patterns 640. Hence, in the present embodiment, the intersections 624, parts of the second conductive patterns 622, and parts of the first conductive patterns 632 are formed on the insulation patterns 140. The maximum overlapping length L2 of each of the insulation patterns 640 and one of the second conductive patterns 622 in the second direction D2 is at least 15 μm. The maximum overlapping length L1 of each of the insulation patterns 640 and one of the first conductive patterns 632 in the first direction D1 is at least 15 μm. Particularly, part of the sidewalls of the insulation patterns 640 are covered by the second conductive patterns 622 (with the relatively large linewidth) rather than the intersections 624. Part of the sidewalls of the insulation patterns 640 are covered by the first conductive patterns 632 (with the relatively large linewidth) rather than first narrow portion 634. As a result, the design described herein is capable of reducing the likelihood of open circuit caused by the reduced linewidth or the reduced thickness of the film layers in the existing design. Furthermore, the profile of the insulation pattern 640 can be rhombic with arc angles aligned opposite in the first direction D1. Therefore, a maximum overlapping length L1 of each of the insulation patterns 640 and one of the first conductive patterns 632 in the first direction D1 can be less than a maximum overlapping length L2 of each of the insulation patterns 640 and one of the second conductive patterns 622 in the first direction D2. Accordingly, the electrically connection between the first narrow portions 634 and the first conductive patterns 632 can be ensured.

In FIG. 15, it shows an embodiment similar to the embodiment of FIG. 14, but the insulation patterns 740 depicted in FIG. 15 has an elongate shape in the extending direction of the first narrow portions 634. In the embodiment of FIG. 15, each of the first conductive patterns 632 covers a portion of one of the insulation patterns 740; and each of the second conductive patterns 622 covers a portion of one of the insulation patterns 740. In addition, a maximum overlapping length L1 of each of the insulation patterns 740 and one of the first conductive patterns 632 in the first direction D1 is greater than a maximum overlapping length L2 of each of the insulation patterns 740 and one of the second conductive patterns 622 in the first direction D2.

To sum up, according to an embodiment of the invention, each of the insulation patterns of the touch panel are not only overlapped with one of the first narrow portions and one of the intersections, but also overlapped with two adjacent ones of the first conductive patterns connected by the one of the first narrow portions. Accordingly, the first narrow portions can be protected from being affected in subsequent manufacturing steps, thus electrically connection between the first narrow portions and the first conductive patterns of each of the first conductive series can be ensured. Moreover, each of the insulation patterns of the touch panel can be overlapped with the two adjacent ones of the second conductive patterns connected by the one of the intersections. Therefore, the likelihood of open circuit in the intersections may be reduced. By partially disposing the non-intersections in the second conductive series (e.g., the second conductive patterns) and/or the first conductive patterns on the surface of the insulation patterns, the edges of the insulation patterns are covered and prevent them from being peeled off. As a result, it is rather unlikely for the conductive series of the touch panel to be poorly manufactured, and the ESD protection can be achieved. That is, the touch panel described herein is characterized by favorable quality and reliability. Last but not least, according to some embodiments of the invention, the conductive portions having the favorable conductivity are arranged between adjacent conductive patterns, so as to enhance the transmission properties of the conductive series.

Although the invention has been described with reference to the embodiments thereof, it will be apparent to one of the ordinary skills in the art that modifications to the described embodiments may be made without departing from the spirit of the invention. Accordingly, the scope of the invention will be defined by the attached claims not by the above detailed description.

What is claimed is:

1. A touch panel comprising:
a substrate;
a plurality of first conductive series disposed on the substrate, each of the first conductive series comprising a plurality of first conductive patterns arranged in a first direction and a plurality of first narrow portions, each of the first narrow portions connecting between two adjacent ones of the first conductive patterns of the first conductive patterns of each of the first conductive series;
a plurality of second conductive series disposed on the substrate, insulated from the first conductive series, each of the second conductive series extends in a second direction and includes a plurality of intersections intersected with the first narrow portions; and
a plurality of insulation patterns located between the first narrow portions and the intersections, so that one of the first narrow portions and a respective one of the intersections intersected with the one of the first narrow portions are separate, wherein an edge of each of the insulation patterns and one of the first conductive patterns of each of the first conductive series partially overlap, wherein a maximum overlapping length of each of the insulation patterns and the one of the first conductive patterns in the first direction is at least 15 μm.

2. The touch panel as recited in claim 1, wherein an overlapping area of each of the insulation patterns and the one of the first conductive patterns is not more than half an area of the first conductive pattern.

3. The touch panel as recited in claim 1, wherein each of the second conductive series comprises a plurality of second conductive patterns, and each of the intersections connects between two adjacent ones of the second conductive patterns of each of the second conductive series.

4. The touch panel as recited in claim 3, wherein the second conductive patterns and the intersections are arranged in a continuous manner and are made of a same material.

5. The touch panel as recited in claim 3, wherein a maximum overlapping length of each of the insulation patterns and one of the second conductive patterns in the second direction is at least 15 μM.

6. The touch panel as recited in claim 3, wherein an overlapping area of each of the insulation patterns and one of the second conductive patterns is not more than half an area of the second conductive pattern.

7. The touch panel as recited in claim 1, wherein a profile of the insulation pattern is rhombic, circular, elliptic, or other shape with arc edges or arc angle.

8. The touch panel as recited in claim 1, wherein the first conductive patterns and the first narrow portions are arranged in a continuous manner and are made of a same material.

9. The touch panel as recited in claim 1, wherein each of the first conductive patterns has a first portion and a second portion electrically connected each other, each of the insulation patterns is formed on a respective one of the first narrow portions and two adjacent ones of the first portions of the first conductive pattern connected by the respective first narrow portion, the second portion of the first conductive pattern covers the first portion and the insulation pattern, the first narrow portions and the first portions of the first conductive patterns are made of a same material.

10. The touch panel as recited in claim 9, wherein a conductivity of the first portion of each of the first conductive patterns is greater than a conductivity of the second portion of each of the first conductive patterns.

11. The touch panel as recited in claim 1, wherein each of the first conductive series further comprises a plurality of first conductive portions, each of the first conductive portions is located between two adjacent first narrow portions and connects between two adjacent ones of the first conductive patterns, and a conductivity of each of the first conductive portions is greater than a conductivity of each of the first conductive patterns.

12. The touch panel as recited in claim 11, wherein each of the first conductive patterns is located between one of the first narrow portions and one of the first conductive portions.

13. The touch panel as recited in claim 1, further comprising an insulating protection layer at least covering the first conductive series, and the insulating protection layer being located between the first conductive series and the second conductive series.

14. The touch panel as recited in claim 13, wherein a thickness of the insulating protection layer is less than a thickness of the insulation pattern.

15. The touch panel as recited in claim 1, wherein each of the second conductive series comprises a plurality of second conductive patterns and a plurality of second conductive portions, and each of the second conductive portions is located between two adjacent intersections, each of the second conductive patterns is located between each of the second conductive portions and each of the intersections, an area of each of the second conductive patterns is greater than an area of each of the second conductive portions and an area of each of the intersections, and a conductivity of each of the second conductive portions is greater than a conductivity of a material of each of the second conductive patterns.

16. The touch panel as recited in claim 15, wherein the insulation patterns are not overlapped with the second conductive portions.

17. The touch panel as recited in claim 1, wherein the insulation patterns and a region of the second conductive series excluding the intersections partially overlap.

18. A touch panel comprising:
a substrate;
a plurality of first conductive series disposed on the substrate, each of the first conductive series comprising a plurality of first conductive patterns arranged in a first direction and a plurality of first narrow portions, each of the first narrow portions connecting between two adjacent ones of the first conductive patterns of the first conductive patterns of each of the first conductive series;
a plurality of second conductive series disposed on the substrate, insulated from the first conductive series, each of the second conductive series extends in a second direction and includes a plurality of intersections intersected with the first narrow portions; and
a plurality of insulation patterns located between the first narrow portions and the intersections, so that one of the first narrow portions and a respective one of the intersections intersected with the one of the first narrow portions are separate, wherein the insulation patterns and the first conductive patterns partially overlap.

19. The touch panel as recited in claim 18, wherein the insulation patterns and a region of the second conductive series excluding the intersections partially overlap.

20. The touch panel as recited in claim 19, wherein the region of the second conductive series excluding the intersections partially covers the insulation patterns.
